(19) United States
(12) Patent Application Publication
(10) Pub. No.: US 2026/0231340 A1
(43) Pub. Date: Aug. 6, 2026

(54) COMPONENT ISOLATION DURING PLASMA EXPOSURE

(71) Applicant: SKYWORKS SOLUTIONS, INC., Irvine, CA (US)

(72) Inventors: Miguel Camargo Soto, Mexicali (MX); Jorge Luis Valdivia Sandoval, Mexicali (MX); Aldrin Quinones Garing, Mexicali (MX)

(21) Appl. No.: 19/454,557

(22) Filed: Jan. 21, 2026

Related U.S. Application Data
(60) Provisional application No. 63/752,144, filed on Jan. 31, 2025.

(51) Int. Cl. H05K 3/28; H05K 1/181

(52) U.S. Cl. CPC H05K 3/284; H05K 1/181; H05K 2201/10015; H05K 2203/0759

(57) ABSTRACT

A method for electrically isolating an electrical component in preparation for plasma cleaning. The method comprises dispensing a layer of electrically non-conductive epoxy onto the electrical component so as to cover the electrical component with the electrically non-conductive epoxy. The method further comprises curing the electrically non-conductive epoxy so as to electrically isolate the electrical component.

### CROSS-REFERENCE TO RELATED APPLICATIONS

This application claims priority under 35 U.S.C. § 119(e) to U.S. Provisional Patent Application Ser. No. 63/752,144, titled “COMPONENT ISOLATION DURING PLASMA EXPOSURE,” filed Jan. 31, 2025, the entire content of which is incorporated herein by reference for all purposes.

### BACKGROUND

### Field

Aspects and embodiments disclosed herein relate to the field of semiconductor fabrication and packaging. More specifically, the present disclosure relates to component isolation for semiconductor fabrication and packaging processes.

### Description of the Related Technology

Wire-bonding is a common way of making electrical interconnections between electronic components, such as integrated circuits and printed circuit boards (PCB), during fabrication and packaging of semiconductor devices. Wire-bonding involves using a wire (e.g., copper, gold, silver, alloyed aluminum, palladium, etc.) to form an interconnection between respective contacts. Wire-bonding is generally considered to be cost-effective and flexible. Wire-bonding can be automated by using a wire-bonding machine (also known as wire-bonders). An example of a wire-bonder is the KNS model ICONN PLUS or PROCU Plus. Prior to wire-bonding, the components undergo plasma processing, or plasma cleaning. Plasma processing is a cleaning technique that assures good bondability during the wire-bonding process. Without plasma processing, weak bonds may result in diminished yields, loss of material (e.g., wire), unreliable interconnections, and so on.

### SUMMARY

According to one embodiment there is provided a semiconductor processing method for electrically isolating an electrical component in preparation for plasma cleaning. The method comprises dispensing a layer of electrically non-conductive epoxy onto the electrical component so as to cover the electrical component with the electrically non-conductive epoxy, and curing the electrically non-conductive epoxy so as to electrically isolate the electrical component.

In one example, the electrical component is a surface mount component.

In one example, the electrical component is a capacitor.

In one example, the capacitor is disposed on a printed circuit board.

In one example, the semiconductor processing method further comprises attaching a semiconductor die to the printed circuit board using the electrically non-conductive epoxy.

In one example, a volume of dispensed electrically non-conductive epoxy is at least 30% larger than a volume of the electrical component.

In one example, the electrical component has a size of at least 0.25 mm by 0.125 mm.

In one example, the semiconductor processing method further comprises positioning a non-conductive epoxy dispenser above the electrical component, the non-conductive epoxy dispenser being configured to dispense the electrically non-conductive epoxy.

In one example, the non-conductive epoxy dispenser is a needle.

In one example, the semiconductor processing method further comprises initiating a plasma cleaning process.

In one example, the plasma cleaning process uses argon plasma.

In one example, curing the electrically non-conductive epoxy includes oven curing the electrically non-conductive epoxy.

In one example, the semiconductor processing method further comprises initiating a wire-bonding process.

In one example, the electrically non-conductive epoxy is free from metallic elements.

In one example, the method further comprises programming a die attach machine to dispense the layer of electrically non-conductive epoxy.

In one example, the die attach machine comprises a dispenser for dispensing the layer of electrically non-conductive epoxy.

According to another embodiment there is provided a non-transitory computer-readable medium on which are encoded instructions for implementing the semiconductor processing method.

According to another embodiment there is provided a computer program product comprising instructions which, when executed by a processor, cause the processor to implement the semiconductor processing method.

According to another embodiment there is provided an electrical assembly for plasma cleaning. The electrical assembly comprises an electrical component, and a layer of electrically non-conductive epoxy, the electrically non-conductive epoxy covering the electrical component so as to electrically isolate the electrical component.

In one example, the electrical component is a capacitor.

In one example, the electrical assembly further comprises a printed circuit board on which the electrical component is disposed.

According to another embodiment there is provided a system for preparing an electrical assembly for plasma cleaning. The system comprises a dispenser for dispensing a layer of non-conductive epoxy on an electrical component, and an oven for curing the layer of non-conductive epoxy so as to electrically isolate the electrical component.

In one example, the system further comprises processing means configured to control the movement of the dispenser so as to enable positioning of the dispenser above the electrical component for the dispensing of non-conductive epoxy.

In one example, the processing means are further configured to control the dispensing of non-conductive epoxy by the dispenser.

In one example, the system further comprises imaging means configured to capture an image of the electrical component.

In one example, the system further comprises a user interface configured to display the image of the electrical component and with which an operator can interact.

In one example, the user interface is configured to enable the operator to identify a position of the electrical component from the image of the electrical component.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the aspects and embodiments disclosed. In the figures, each identical or nearly identical component that is illustrated in various figures is represented by a like numeral. For purposes of clarity, not every component may be labeled in every figure. In the figures:

FIG. 1A is a schematic diagram of a wire-bond connection without a perceived failure;

FIG. 1B is a schematic diagram of a wire-bond connection with a perceived failure;

FIG. 1C is a schematic diagram of another wire-bond connection with a perceived failure;

FIG. 1D is a schematic diagram of another wire-bond connection with a perceived failure;

FIG. 1E is a schematic diagram of another wire-bond connection with a perceived failure;

FIG. 2A provides a top-down view of a section of a die and lead-frame fingers with wire-bonding;

FIG. 2B provides a top-down view of the section of the die and lead-frame fingers shown in FIG. 2A without wire-bonding;

FIG. 3A provides a top-down view of the same section of the die and lead-frame fingers shown in FIGS. 2A and 2B during a plasma cleaning process;

FIG. 3B provides a cross-sectional view of the same section of the die and lead-frame fingers shown in FIGS. 2A and 2B during a plasma cleaning process;

FIG. 4 is a diagram of a plasma cleaner;

FIG. 5A provides a schematic diagram of a printed circuit board (PCB);

FIG. 5B provides a schematic diagram of a portion of a PCB including capacitors;

FIG. 6 is an energy-dispersive X-ray spectroscopy analysis of a capacitor of the PCB of FIG. 5B following three rounds of known plasma cleaning;

FIG. 7A illustrates an example of an act for attaching a GaAs die to a substrate;

FIG. 7B illustrates an example of another act for attaching a GaAs die to a substrate;

FIG. 8 is a schematic diagram of an epoxy dispensing needle;

FIG. 9 is a flowchart of a component isolation method according to aspects of the present disclosure;

FIG. 10 is a schematic diagram of a die attach machine;

FIG. 11 is a schematic diagram of non-conductive epoxy being dispensed onto an electrical component according to aspects of the present disclosure;

FIG. 12 is a schematic diagram of a known capacitor;

FIG. 13 is a diagram of a PCB on which an electrical component has undergone component isolation according to aspects of the present disclosure;

FIG. 14 is a flowchart of a method of programming a known die attach machine for component isolation according to aspects of the present disclosure;

FIG. 15 is a schematic diagram of a PCB comprising reference elements; and

FIG. 16 is a graph comparing yield against number of plasma processes and use of component isolation according to aspects of the present disclosure.

### DETAILED DESCRIPTION

Aspects and embodiments described herein are directed to semiconductor processing methods and apparatuses for electrically isolating an electrical component prior to plasma cleaning, preventing leakage failures.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

There are many causes for failures of bonds of semiconductor die to packages, boards or modules. These causes include wear-out of bonding tools, oxidation of the bonding wires or bonding materials, and contamination of bonding sites on the die, package, or module. In some instances, semiconductor devices with poorly bonded die are scrapped and a large financial loss is incurred. As a result, there is a desire for a reliable and effective technique to remove contamination that is difficult to remove with conventional approaches.

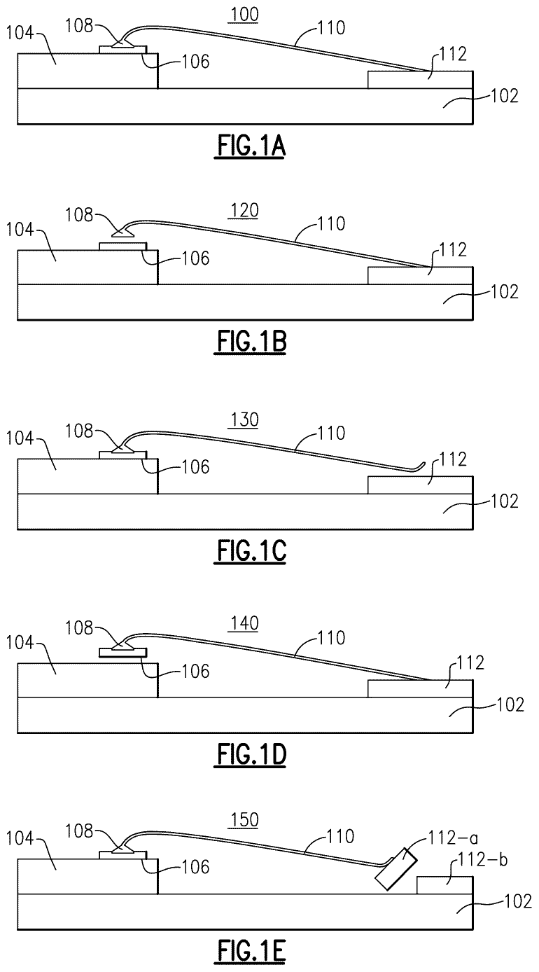

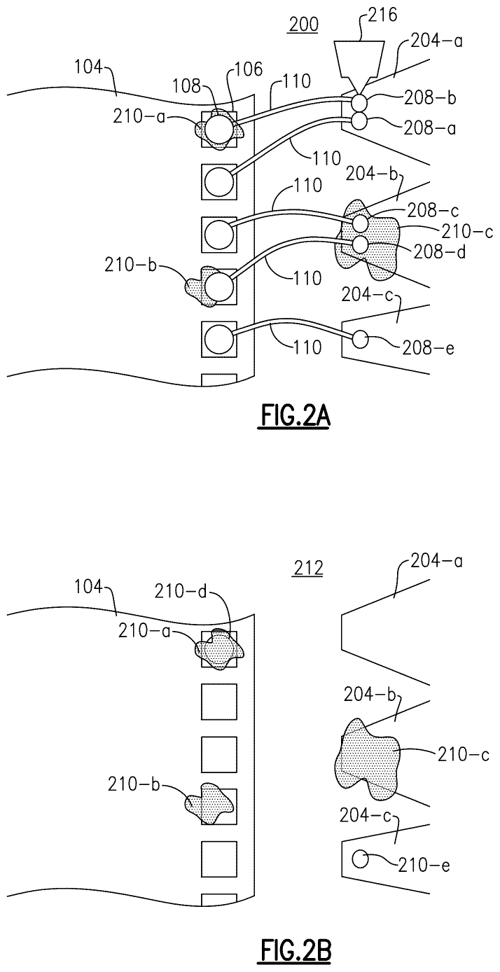

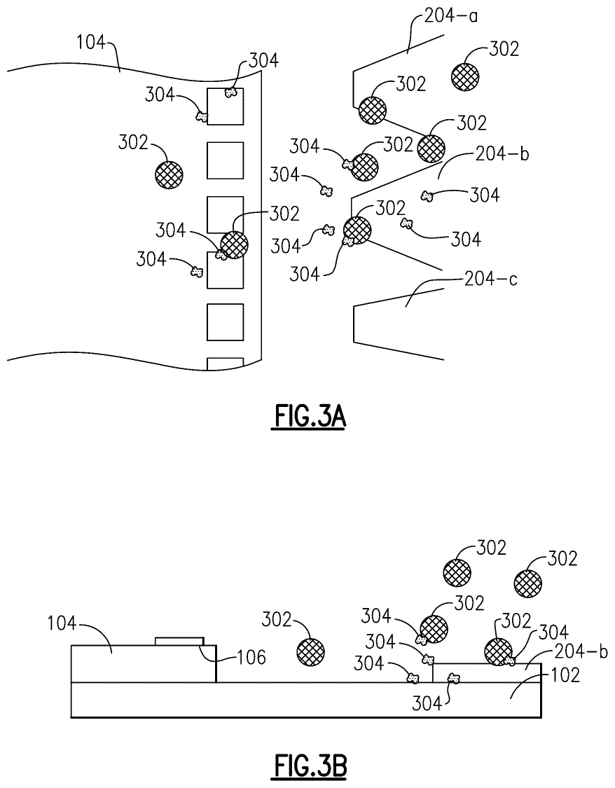

FIGS. 1A to 1E provide a visual comparison of a few different types of failure modes for wire-bonded parts. FIG. 1A illustrates a cross-sectional view 100 of a wire-bond connection without a perceived failure. In FIG. 1A, a bond pad 106 is attached to a die 104. A metal deposit 108 is attached to bond pad 106, and is a part of wire 110. Wire 110 is properly bonded to metallization 112 on substrate 102. In some embodiments, metallization 112 is a part of a lead frame (e.g., a lead frame finger) or another die package component. In some embodiments, FIGS. 1A-1E each illustrate an example of a wire-bond connection after performance of a “pull test” on the connection. For example, the connection between bond pad 106 and metallization 112 is tested by pulling on wire 110 in an upward direction.

Wire-bonding is an electrical interconnection technique using thin metallic wires and a combination of heat, pressure, and/or ultrasonic energy. Wire-bonding is a solid phase welding process, where two metallic materials (e.g., wire and pad surface or wire and PCB lead surface) are brought into contact. Ideally, once the surfaces are in contact, electron sharing or inter diffusion of atoms takes place, resulting in the formation of a wire-bond.

FIG. 1B illustrates a cross-sectional view 120 of one type of failed wire-bond connection. Here, metal deposit 108 has detached from bond pad 106 after the performance of a stress test (e.g., a pull test on wire 110). In some embodiments, metal deposit 108 lifts off from bond pad 106 due to poor bonding technique (e.g., bad placement of metal deposit 108 and/or not enough pressure or heat applied to metal deposit 108). In some embodiments, this wire-bonding failure occurs due to a poor selection of interfacing metals (e.g., the metal of bond pad 106 and the metal of deposit 108 do not meld well together). However, in some embodiments, metal deposit 108 lifts off from bond pad 106 due to poor surface conditions on bond pad 106. For example, bond pad 106 has a rough surface, preventing the formation of a good bond between bond pad 106 and metal deposit 108. In another example, bond pad 106 has contamination on its surface, and some or all of metal deposit 108 makes contact with that contamination. As a result of metal deposit 108 making contact with the contamination, it is easy to pull metal deposit 108 off of bond pad 106 since the contamination-to-pad and contamination-to-deposit connections are each relatively weak.

FIG. 1C illustrates a cross-sectional view 130 of another type of failed wire-bond connection. In some embodiments, a wire-bond failure occurs at the interface between wire 110 and metallization 112. Similar to the failure shown in FIG. 1B, wire 110 may lift off at the interface to metallization 112 due to poor bonding technique, poor selection of interfacing metals, or poor surface conditions at metallization 112. One source of poor surface conditions at metallization 112 is a build-up of contamination.

In some embodiments, contamination at any bonding surface of a package (including bond pad 106 or metallization 112) consists of organic and/or inorganic material. For example, the contamination may be a deposit of epoxy that has spilled over from another region, over the bonding surface. In another example, metal fragments may contaminate a bonding surface, resulting in an uneven location for wire-bonding, and sites with poor surface connectivity. In some embodiments, metal contamination occurs from metal splash resulting from neighboring bonded sites. For example, a bond pad adjacent to bond pad 106 may have been formed with excessive pressure, causing some metal of that bond pad to “splash” onto bond pad 106. This example illustrates that semiconductor devices with bad initial contamination can result in additional contamination problems if dealt with incorrectly. For example, if it is observed that a batch of semiconductor devices are routinely failing wire-bond pull tests, one approach to fixing this problem is to increase wire-bond application pressure, inadvertently creating another source of contamination.

FIG. 1D illustrates a cross-sectional view 140 of another type of failed wire-bond connection. In some embodiments, bond pad 106 lifts off of die 104 during a stress test such as a wire-bond pull test. In some embodiments, this type of failure is a result of cracking underneath a bonded bond pad, due to excessive wire-bonding application pressure. FIG. 1E illustrates a cross-sectional view 150 of another type of failed wire-bond connection. In FIG. 1E, the failure occurs at metallization 112, which fractures and breaks into metallization 112-a and metallization 112-b under a stress test of the wire-bond. This may also be caused by excessive wire-bond application pressure at the interface between wire 110 and metallization 112-a, and a resulting fracture in one or more areas around the interface. As described earlier, increased bonding pressure is one approach taken after observing several failed wire-bond stress tested parts.

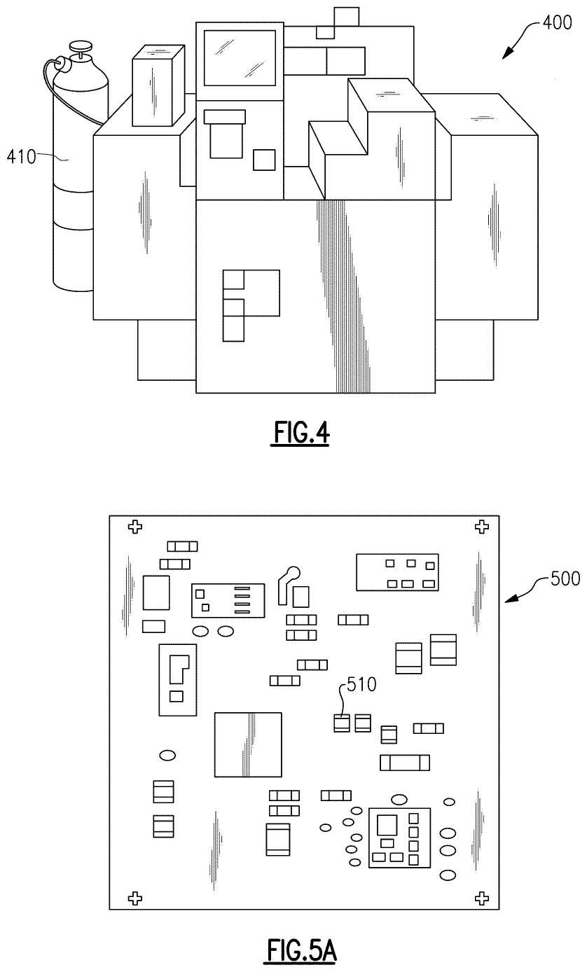

FIG. 2A provides a top-down view 200 of a section of wire-bonding between die 104 and lead-frame fingers 204-a, 204-b and 204-c. In top-down view 200, five adjacent bond pads 106 of die 104 are shown with wire-bonds 110 to locations on a lead frame package (e.g., finger 204-a, finger 204-b, and finger 204-c) . As shown earlier in FIGS. 1A-1E, a metal deposit 108 is located on each bond pad 106 that is wire-bonded, with a wire 110 attached to a respective bond site 208-a, 208-b, 208-c, 208-d, or 208-e at a respective location on the lead frame package. FIG. 2A also shows capillary 216 of a wire-bonding machine or tool. A capillary 216 is a specialized tool for depositing metal to create wire-bonds, through a hollowed-out tip. In this example, capillary 216 just finished creating a wire-bond from a bond pad 106 to bond site 208-a on lead frame package finger 204-a.

FIG. 2A also illustrates several examples of contamination on regions of die 104 and lead frame package. For example, contamination 210-a is located over a bond pad 106, which likely created a weak connection between bond pad 106 and metal deposit 108 during the formation of a wire-bond. Additionally, in the examples of FIG. 2A, there is contamination 210-b on a portion of another bond pad, and contamination 210-c on a portion of lead frame package finger 204-b interfering with the formation of additional wire-bond connections. As mentioned earlier, these contaminations may include organic or inorganic material, such as dust, hair, skin cells, metal fragments, epoxy, adhesives, oxides, or moisture.

FIG. 2B provides a top-down view 212 of the same section of die 104 and lead-frame fingers 204-a, 204-b, and 204-c shown in FIG. 2A, with the wire-bonds omitted. Typically, if a wire-bonded semiconductor part performs poorly in a stress test such as a pull test, the part is scrapped and written off as a cost of doing business. The wire-bonds of the contaminated device shown in FIG. 2A would likely fail such a stress test, causing the device to be scrapped, despite other components of the semiconductor device still having value.

Plasma processing, or plasma cleaning, is a known process that is used to prepare a semiconductor device and substrate (i.e., die 104 and lead-frame fingers 204-a, 204-b, and 204-c) for wire-bonding. Plasma cleaning removes contaminants from the semiconductor device and substrate in preparation for the wire-bonding process.

Plasma is formed by ionizing certain gases to create charged particles. In some embodiments, the plasma cleaning phase is performed in a plasma chamber with a vacuum pump to extract contaminants. The plasma particles bond to contaminants, and in some instances, break molecules of contaminants apart. FIG. 3A and FIG. 3B illustrate exemplary plasma particles 302 bonding to at least some contamination particles 304, to be eventually vacuumed out of the plasma chamber. A known plasma cleaner 400 is the Panasonic model NM-EFP1A illustrated in FIG. 4. In this example, the plasma is created from argon (Ar) gas. The plasma cleaner 400, therefore, comprises a source of argon gas 410. The skilled person will understand, however, that in other examples, other gases may be used to create the plasma for plasma cleaning. An example of another commonly used gas is oxygen. In other examples, a mixture of different gases are used. For example, a mixture of oxygen and argon.

The removal of contaminants using plasma cleaning is important for ensuring good bondability. Plasma cleaning improves the bond strength of wire-bonds which, in turn, leads to a decrease in bonds that do not pass quality control checks such as the wire pull test described above. This, in turn, reduces the number of devices that are scrapped. Yield is, thereby, increased. Plasma cleaning is, therefore, considered an important step in preparing for wire-bonding.

In many electronic applications, electronic circuits such as radio-frequency (RF) circuits are implemented such that the components are mounted on the surface of a substrate such as a packaging substrate or a printed circuit board (PCB). Such components are commonly referred to as surface-mount technology (SMT) devices, or as surface-mount devices (SMDs).

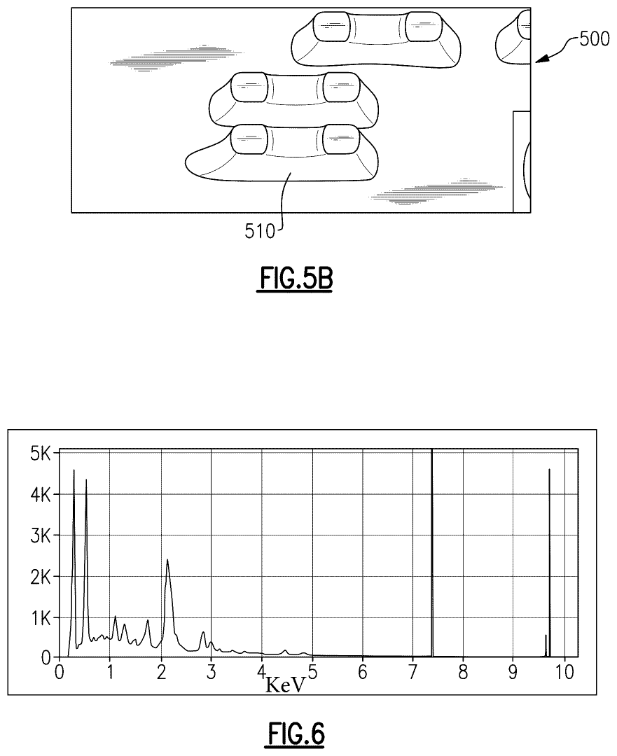

As explained above, plasma cleaning (or plasma processing) prior to wire-bonding facilitates good bondability. However, some surface-mount electrical components on a PCB experience diminished electrical performance as a result of the plasma process. More specifically, capacitors 510, shown on a PCB 500 in FIGS. 5A and 5B, have been observed to show a drastic reduction in resistance. This reduction in resistance can be validated using an external ohmmeter. The cause of the reduction in resistance is a build up of gold (Au) ions between the terminals of the capacitor 510 that occurs during the plasma cleaning. The Au ions come from the Au coated PCB 500 lead fingers. During the plasma cleaning process, the Au ions migrate to the capacitor 510. This causes a current leakage problem. Plasma cleaning effectively expires after a period of time, for example, after 6 to 12 hours. In other words, after a period of time post-plasma cleaning elapses, it can no longer be relied upon that the cleaned components are still contaminant free. Once expired, the plasma cleaning process should be repeated. An increase in the number of plasma cleaning rounds worsens or exacerbates the current leakage problem. FIG. 6 shows energy-dispersive X-ray spectroscopy analysis of the capacitor 510 in FIG. 5B following three rounds of plasma cleaning. Au is detected on a lateral sidewall of the capacitor 510. The electrical performance of the capacitor 510 has, therefore, been compromised. It would be desirable to protect key components such as capacitors from such contamination.

Some solutions to this problem rely on reducing the plasma process time. In other words, the Ar exposure time. This, however, is not a satisfactory solution because reduced plasma exposure time leads to a reduction in cleaning efficacy prior to wire-bonding. This leads to an increased rate of failed wire-bonding. Additionally, particularly sensitive components are still affected by Au ion migration. There, therefore, exists a desire for a more effective and reliable solution.

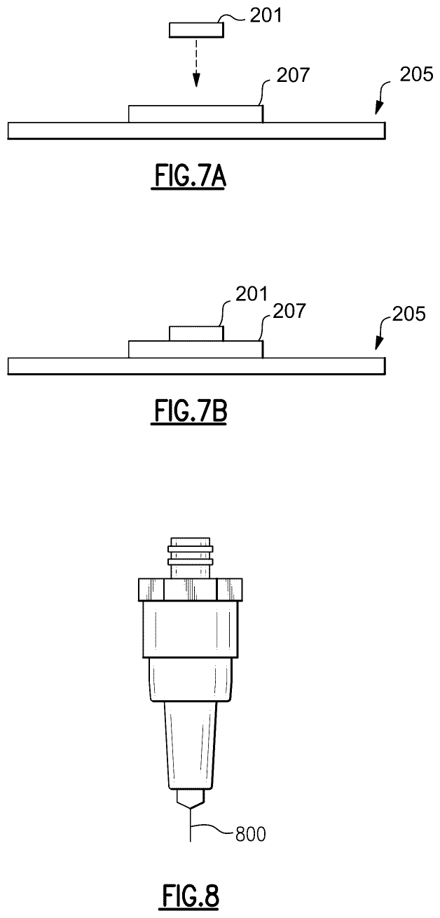

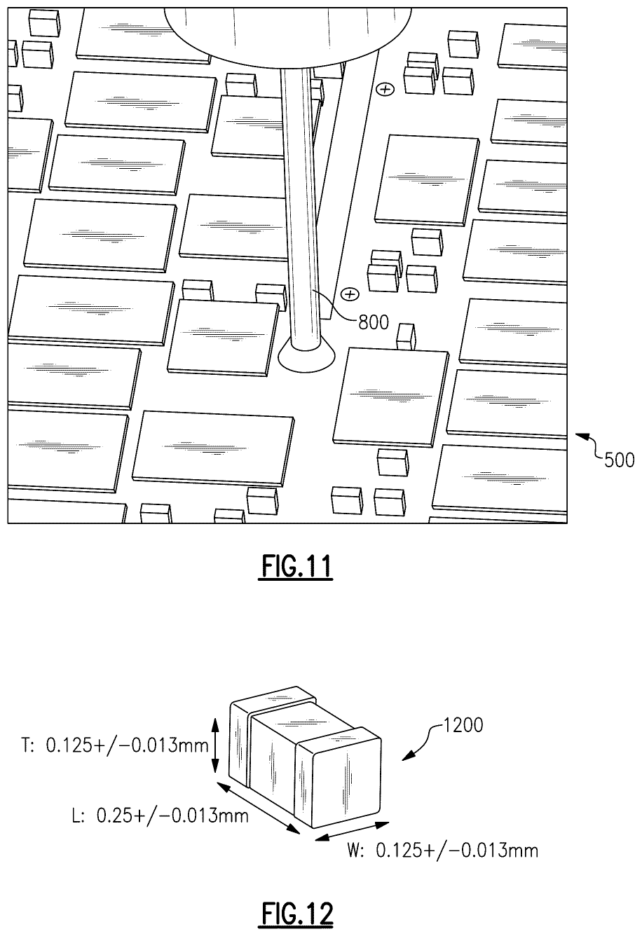

Prior to plasma processing, semiconductor dies (e.g., gallium arsenide (GaAs) or silicon (Si) dies) are bonded or attached to a PCB. This process is known as the die attach process. In this process, an adhesive is applied to the PCB and the semiconductor dies are placed on the PCB substrate. This process is carried out using a die attach machine. An example of a known die attach machine is the Datacon EVO 2200 (see discussion of FIG. 11 below). FIGS. 7A-7B show an example sequence of attaching a GaAs die to a substrate using a process that incorporates the use of a conductive adhesive to attach the die to the substrate. As illustrated, a singulated GaAs die 201 is arranged to be attached to a substrate 205 by die attach pad 207 via a conductive adhesive such as epoxy. The substrate 205 is a printed circuit board for an electronic device. The die attach machine uses a dispenser to dispense the adhesive onto the PCB. In this example, the dispenser is a needle 800 as shown in FIG. 8 and the adhesive is epoxy. The epoxy can be either non-conductive or conductive depending on the implementation in question. Once the dies are in place, the epoxy is oven cured to secure their positioning. An example oven is the Vision Semicon model VSPO-4CM. The inventors have acknowledged that although the use of epoxy for attaching dies to a PCB is known, the use of non-conductive epoxy to electrically isolate components is not known. In other words, the use of non-conductive epoxy to cover the electrical components is not known. As explained below, this provides an effective solution to the current leakage problem.

According to some aspects of the present disclosure, a semiconductor processing method for electrically isolating an electrical component prior to plasma cleaning is provided.

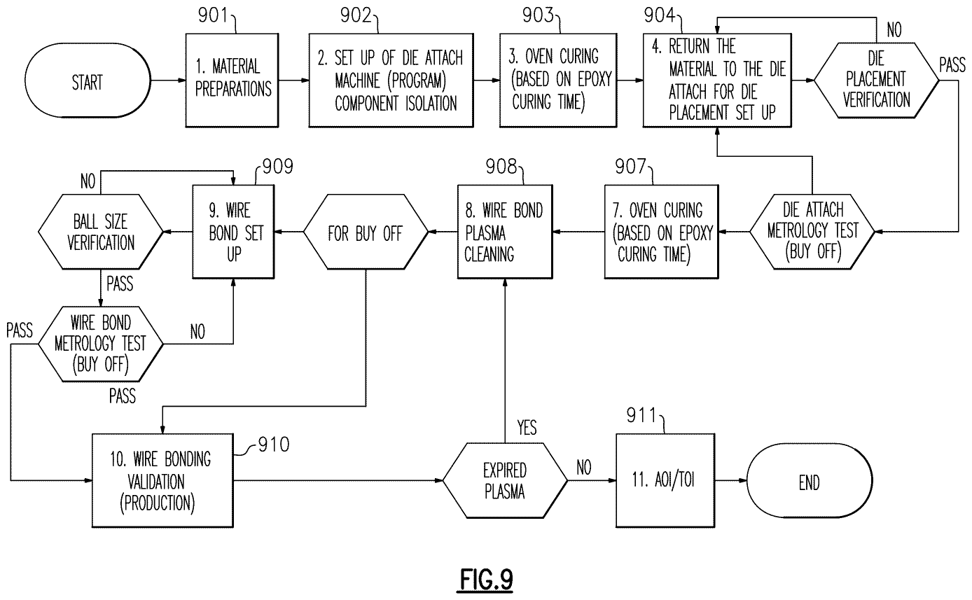

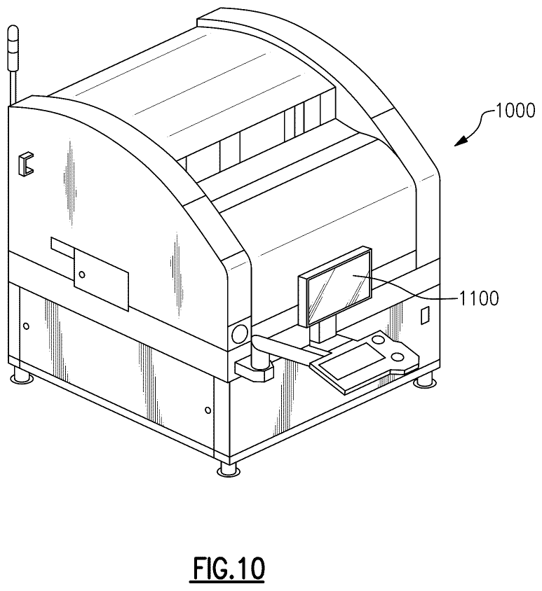

The flowchart of FIG. 9 illustrates an example method for electrically isolating an electrical component according to aspects of the present disclosure. The method involves the following steps:

Step 901: Obtaining and preparing the materials (e.g., PCB, semiconductor dies, surface mount components) for the subsequent stages of the process.

Steps 904 to 907: A die attach process as described above, including the attachment of semiconductor dies to a substrate using epoxy. More specifically, in this example, the attachment of GaAs or Si dies to a PCB. At step 907, in this example, the epoxy is oven-cured. This is to durably attach the dies to the PCB substrate as described above.

Step 908: A plasma cleaning process as described above to remove contaminants ahead of a wire-bonding process. More specifically, in this example, the removal of contaminants using Ar plasma.

Step 910: A wire-bonding process as described above that includes making electrical interconnections between electronic components, such as the semiconductor dies and PCB.

Step 911: Inspection processes (AOI=automatic optical inspection and TOI=thorough optical inspection as will be understood by the person skilled in the art). The TOI operation can include a number of processes. These processes can include inspecting the PCB to identify individual module substrates that are potentially defective, marking the individual module substrates that are potentially defective, and counting the number of potentially defective individual module substrates. The TOI operation may be performed by one or more systems, such as a PCB imaging module, as will be known and understood by the person skilled in the art.

The ‘buy off’ stages in the flowchart of FIG. 9 refer to intermediate approval processes. These processes determine that previous processes have been implemented successfully before progressing to subsequent processing stages. Furthermore, before step 911, it is determined whether the plasma cleaning of step 908 has now expired. In other words, if plasma cleaning is due to be repeated. If so, the plasma cleaning process is implemented again. If not, the method progresses to inspection.

Steps 902 and 903 are significant and do not form part of known manufacturing methods. At step 902, the die attach machine is set up. In this example, this is the same die attach machine that is used for the die attach process of steps 904 to 907. In this example, the die attach machine is the Datacon EVO 2200. Such an example die attach 1000 machine is shown in FIG. 10. However, the die attach machine 1000 is set up to execute a ‘component isolation’ program. This programming is significant and is described in more detail below. The skilled person will also understand that in other examples, the die attach machine 1000 used to execute the component isolation process and the die attach process will be different. Furthermore, the skilled person will understand that other known die attach machines can be used. The die attach machine 1000 comprises a processing system. When instructed to execute the ‘component isolation’ program, the dispenser 800 is instructed to position itself above an electrical component that is to be electrically isolated. In this example the dispenser 800 is a needle, as described above and shown in FIG. 8, however, in other examples, the skilled person will understand that other means for dispensing may be implemented. FIG. 11 shows a dispenser 800 positioned above a component. By positioning itself above the electrical component, the dispenser is configured to dispense fluid material such that the material covers the component. In this example, the component is a capacitor. More specifically, the capacitor is a HiQ capacitor. Even more specifically, the capacitor is a 08004 size Hi-Q/GHM01 series capacitor. FIG. 12 illustrates such a capacitor 1200 and its dimensions. As explained above, capacitors 1200 are particularly susceptible to degraded electrical performance as a result of the plasma cleaning process. However, the skilled person will understand that this component isolation method can be applied to other key electrical components. Examples of other components that may benefit from isolation include, but are not limited to, semiconductor dies and resistors. More specifically, the component isolation method will be particularly applicable to surface mount components. In this example, the component isolation method can be applied to components as small as 0.25 mm×0.125 mm. However, the skilled person will understand that this lower bound could be further lowered by using an alternative die attach machine and/or means of dispensing non-conductive epoxy.

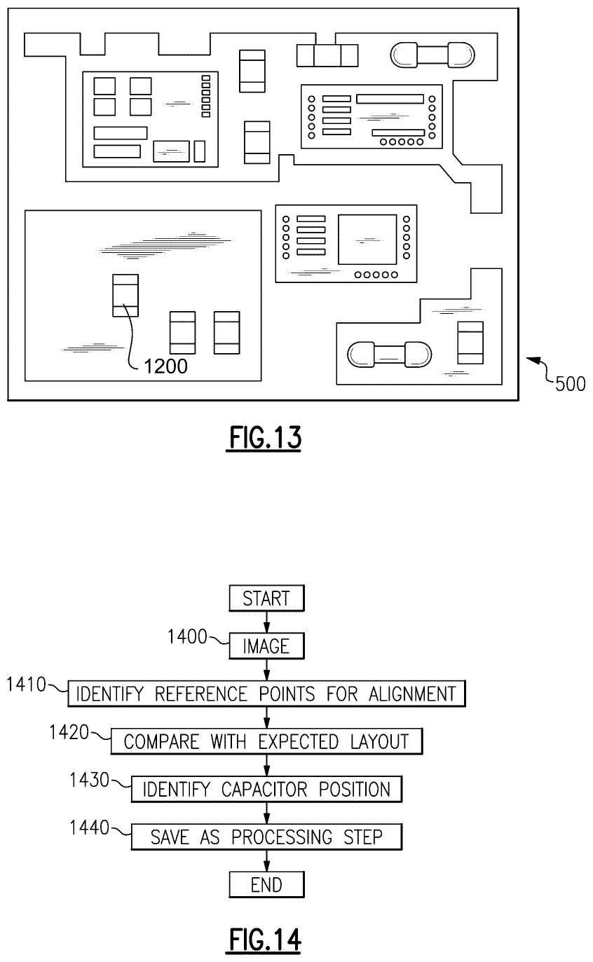

Once the dispensing needle 800 is positioned above the component (e.g., capacitor 1200) to be isolated, the dispensing needle 800 dispenses non-conductive epoxy. More specifically, the dispensing needle 800 dispenses an amount of non-conductive epoxy that forms a layer covering the component. By non-conductive, it is meant that the epoxy is free from metallic elements. This ensures that that the non-conductive epoxy is able to electrically isolate the component it is covering. In this example, the non-conductive epoxy is the Sumitomo Bakelite Sumiresin Excel CRM-1576A. Furthermore, to ensure electrical isolation, the amount of epoxy dispensed by the dispensing needle 800 should cover the component entirely. That is, there should be no part of the component left exposed. To further facilitate electrical isolation, the layer of non-conductive epoxy should have a thickness larger than a dimension of the component itself. In this example, where the component is a capacitor 1200, the volume of the non-conductive epoxy deposited should be at least 30% larger than the volume of the capacitor 1200. The process is then repeated and epoxy is deposited on any other components that are to be isolated. Once all the utilized non-conductive epoxy has been deposited, an oven curing process is initiated. In other words, oven curing is initiated once all the electrical components that have been identified as benefiting from component isolation are covered in a layer of non-conductive epoxy. In this example, the Vision Semicon model VSPO-4CM is used to oven cure the epoxy. In other words, the same oven that is used for oven curing during the die attach process of step 907 of the flowchart of FIG. 9. However, the skilled person will understand that other models will be suitable. The curing time will depend on the amount of non-conductive epoxy used. The curing temperature will also depend on the type of epoxy used. In this example, a standard curing condition is 60 minutes at 100 degrees Celsius. Alternatively, 15 minutes at 150 degrees Celsius would also be sufficient. FIG. 13 shows an image of capacitors on which the described component isolation method has been applied. As is evident in the image of FIG. 13, a region of shading surrounds the capacitor 1200. This is the non-conductive epoxy.

As explained above, the way in which the die attach machine is programmed is significant and is described with reference to FIG. 11. In this example, the die attach machine 1000 comprises a processing system. As explained above, the processing system is configured to control the movement of the dispenser. In other words, to control the positioning of the dispenser. The processing system is further configured to control the dispensing of the non-conductive epoxy. The processing system may, in some embodiments include a general purpose processor or CPU, a special purpose processor or programmable state machine, or combinations of the above. In this example, the die attach machine further comprises a user interface 1100. In this example, the user interface is configured to enable an operator to program the die attach machine. In other words, the user interface is configured to enable the operator to input a set of instructions which, when executed by the processing system, controls the movement of the dispenser and the dispensing of non-conductive epoxy. In this example, the user interface 1100 comprises a screen. The screen is configured to display the imaged PCB (see below). In this example, the die attach machine further comprises storage means. Said storage means are configured to store the set of instructions input by the operator, and may include, without limitation, RAM memory, ROM memory, flash or SSD memory, or any other type of memory known in the art. In this way, the set of instructions can be retrieved and re-executed at a later stage. In this example, the die attach machine further comprises imaging means (not shown). In this example, the imaging means is a camera. The camera is configured to image a substrate. In this example, within the context of surface mount technology, the substrate is a PCB. Said PCB comprises electrical components. More specifically, said PCBs comprise components that utilize isolation (e.g., capacitors).

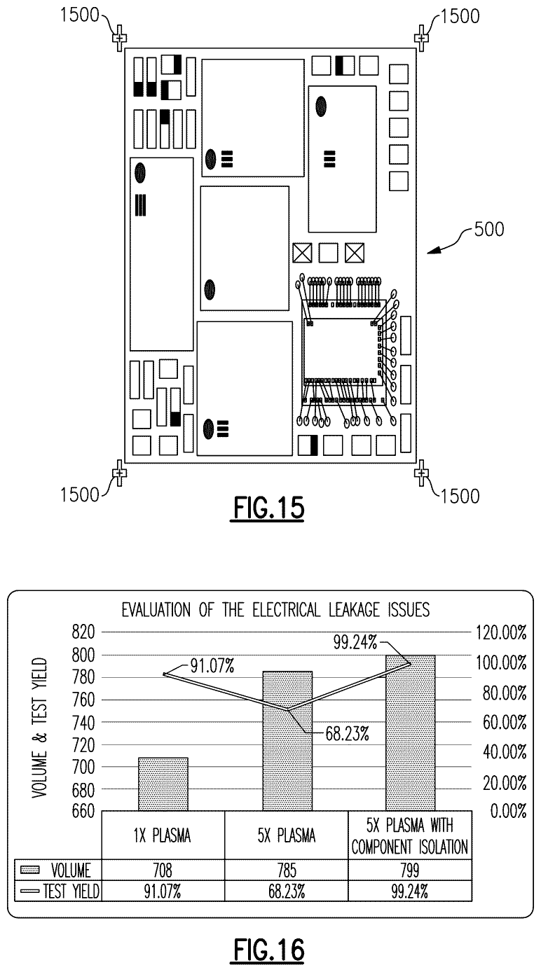

The flowchart of FIG. 14 outlines how the die attach machine is programmed to execute component isolation. At step 1400, the imaging means images the PCB. Said image is displayed on the user interface 1100 of the die attach machine 1000. In this way, an operator can view the imaged PCB. The operator identifies the PCB on the user interface 1100 from the image of the PCB. At step 1410 the operator identifies reference points on the PCB. An example PCB 500 is shown in FIG. 15. In this example, the PCB 500 comprises fiducial markers 1500. The fiducial markers 1500 act as reference points, or reference elements. In this example, the PCB comprises more than one fiducial marker 1500, or reference point. More specifically, the PCB 500 comprises four fiducial markers 1500. The skilled person will understand that, in other examples, other reference elements will be used in addition to, or instead of, fiducial markers. The reference points enable alignment of the imaged PCB 500 with an expected pattern. In this example, the expected pattern is a map of the PCB design. In other words, an expected layout of the PCB and its components. Using the imaged PCB 500 and the reference points 1500, the imaged PCB is compared to the expected pattern using known computer vision techniques (step 1420). Such computer vision techniques, in this example, will be pre-preprogrammed into the die attach machine. However, in other examples, the operator may manually program the computer vision sequence. In this example, any deviations from the expected pattern can be identified so as to identify potential points of error. Once the imaged PCB is aligned with the expected map of the components, the operator can select, via the user interface of the die attach machine, the position of a component to which component isolation is to be applied (act 1430). In this example, as described above, the component is a capacitor. However, the skilled person will understand that other components, such as resistors, may be selected alternatively or in addition to the capacitor. By selecting the position of the capacitor, the position is saved as a position for the dispensing of non-conductive epoxy. In other words, the dispensing of non-conductive epoxy at the identified position of the capacitor is saved as a processing step (step 1440). The operator can then instruct the die attach machine to execute said processing step. Executing said processing steps results in the dispensing of non-conductive epoxy on the specified position. The result is that the capacitor is covered in a layer of non-conductive epoxy.

The graph of FIG. 16 illustrates yield for a component with no isolation after one plasma process and five plasma processes. As expected, the yield decreases significantly with the increase in plasma processes due to the known electrical leakage problem. The graph compares this to the yield for a component with non-conductive epoxy isolation according to aspects of the present disclosure after five plasma processes. The yield is at 99.24%. This is significantly higher than even the component with no isolation after only one plasma process. These results demonstrate the efficacy of the component isolation method.

A method as described above has several advantages. By electrically isolating the component, the problem of electrical leakage due to Au ion contamination is reduced. This enables the component to go through several rounds of plasma cleaning, if necessary. This facilitates effective subsequent wire-bonding processes. As a result, yield may be increased. Furthermore, in addition to electrically isolating the component, the layer of non-conductive epoxy provides a physical barrier. This protects the component from the elements. As a result, sensitive components can be protected from corrosion or moisture which can negatively affect their performance. The physical barrier provided by the non-conductive epoxy further protects the component against mechanical damage. Such mechanical damage may otherwise occur in subsequent processing steps. This, again, increases yield. A further advantage is that the method does not require new equipment. Instead, an existing die attach machine can be programmed to execute a component isolation sequence.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the aspects and embodiments disclosed herein. Accordingly, the foregoing description and drawings are by way of example only, and the scope of the aspects and embodiments disclosed herein should be determined from proper construction of the appended claims, and their equivalents.

What is claimed is:

1. A method for electrically isolating an electrical component in preparation for plasma cleaning, the method comprising:
dispensing a layer of electrically non-conductive epoxy onto the electrical component so as to cover the electrical component with the electrically non-conductive epoxy; and
curing the electrically non-conductive epoxy so as to electrically isolate the electrical component.

2. The method of claim 1 wherein the electrical component is a surface mount component.

3. The method of claim 1 wherein the electrical component is a capacitor.

4. The method of claim 3 wherein the capacitor is disposed on a printed circuit board.

5. The method of claim 1 wherein a volume of dispensed electrically non-conductive epoxy is at least 30% larger than a volume of the electrical component.

6. The method of claim 1 further comprising positioning a non-conductive epoxy dispenser above the electrical component, the non-conductive epoxy dispenser being configured to dispense the electrically non-conductive epoxy.

7. The method of claim 6 wherein the non-conductive epoxy dispenser is a needle.

8. The method of claim 1 further comprising initiating a plasma cleaning process.

9. The method of claim 1 wherein curing the electrically non-conductive epoxy includes oven curing the electrically non-conductive epoxy.

10. The method of claim 1 further comprising initiating a wire-bonding process.

11. The method of claim 1 further comprising programming a die attach machine to dispense the layer of electrically non-conductive epoxy.

12. The method of claim 11 wherein the die attach machine comprises a dispenser for dispensing the layer of electrically non-conductive epoxy.

13. An electrical assembly prepared for plasma cleaning, the electrical assembly comprising:
an electrical component; and
a layer of electrically non-conductive epoxy, the electrically non-conductive epoxy covering the electrical component so as to electrically isolate the electrical component.

14. The electrical assembly of claim 13 wherein the electrical component is a capacitor.

15. The electrical assembly of claim 13 further comprising a printed circuit board on which the electrical component is disposed.

16. A system for preparing an electrical assembly for plasma cleaning, the system comprising:
a dispenser for dispensing a layer of non-conductive epoxy on an electrical component; and
an oven for curing the layer of non-conductive epoxy so as to electrically isolate the electrical component.

17. The system of claim 16 further comprising processing means configured to control movement of the dispenser so as to enable positioning of the dispenser above the electrical component for the dispensing of non-conductive epoxy.

18. The system of claim 17 wherein the processing means is further configured to control the dispensing of non-conductive epoxy by the dispenser.

19. The system of claim 16 further comprising a user interface configured to display an image of the electrical component and with which an operator can interact.

20. The system of claim 19 wherein the user interface is configured to enable the operator to identify a position of the electrical component from the image of the electrical component.
